(19) United States
(12) Patent Application Publication
(10) Pub. No.: US 2024/0365633 A1
(43) Pub. Date: Oct. 31, 2024

(54) DISPLAY DEVICE

(71) Applicant: Samsung Display Co., Ltd., Yongin-Si (KR)

(72) Inventors: Bo Kwang SONG, Yongin-si (KR); Gee Bum KIM, Yongin-si (KR); Kwang Soo BAE, Yongin-si (KR); Min Oh CHOI, Yongin-si (KR)

(21) Appl. No.: 18/409,811

(22) Filed: Jan. 11, 2024

(30) Foreign Application Priority Data
Apr. 28, 2023 (KR) 10-2023-0056159

(51) Int. Cl. H10K 59/38; H10K 59/126; H10K 59/131; H10K 59/35

(52) U.S. Cl. CPC H10K 59/38; H10K 59/126; H10K 59/131; H10K 59/352

(57) ABSTRACT

A display device is disclosed that includes an active area including a first active area and a second active area, pixels disposed in the first active area and the second active area and including respective light emitting elements, a first optical sensor disposed in the first active area and including a first photoelectric conversion element, a second optical sensor disposed in the second active area and including a second photoelectric conversion element, a light blocking member disposed in the first active area and the second active area, including first openings exposing the light emitting elements and a second opening exposing the first photoelectric conversion element, and covering the second photoelectric conversion element, and a first color filter and a second color filter disposed on the light blocking member and overlapping each other above the second photoelectric conversion element.

### CROSS-REFERENCE TO RELATED APPLICATION

This application claims priority from Korean Patent Application No. 10-2023-0056159 filed on Apr. 28, 2023, in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device.

### 2. Description of the Related Art

The importance of display devices has steadily increased with the development of multimedia technology. Accordingly, various types of display devices such as a liquid crystal display device, an organic light emitting display device and the like have been developed.

### SUMMARY

Embodiments of the present disclosure may provide a display device including an optical sensor in which noise included in a signal from an optical sensor may be sensed.

However, embodiments of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a display device includes an active area including a first active area and a second active area, pixels disposed in the first active area and the second active area and including respective light emitting elements, a first optical sensor disposed in the first active area and including a first photoelectric conversion element, a second optical sensor disposed in the second active area and including a second photoelectric conversion element, a light blocking member disposed in the first active area and the second active area, including first openings exposing the light emitting elements and a second opening exposing the first photoelectric conversion element, and covering the second photoelectric conversion element, and a first color filter and a second color filter disposed on the light blocking member and overlapping each other above the second photoelectric conversion element.

In an embodiment, the light blocking member may completely cover the second photoelectric conversion element.

In an embodiment, each of the first color filter and the second color filter may completely cover the second photoelectric conversion element.

In an embodiment, the second active area may be located at an edge of the active area.

In an embodiment, the display device may further include a third color filter disposed in the second opening to overlap the first photoelectric conversion element.

In an embodiment, the first color filter may be a red color filter, the second color filter may be a blue color filter, and the third color filter may be a green color filter.

In an embodiment, the pixels may include first color pixels, second color pixels, and third color pixels.

In an embodiment, the display device may further include first color filters disposed in first openings of a first group exposing light emitting elements of the first color pixels among the first openings, second color filters disposed in first openings of a second group exposing light emitting elements of the second color pixels among the first openings, and third color filters disposed in first openings of a third group exposing light emitting elements of the third color pixels among the first openings.

In an embodiment, the display device may further include a third color filter disposed on the light blocking member and overlapping the first color filter and the second color filter above the second photoelectric conversion element.

In an embodiment, the third color filter may completely cover the second photoelectric conversion element.

According to an embodiment of the present disclosure, a display device includes a substrate including a first active area and a second active area, pixels disposed on the substrate to be located in the first active area and the second active area, and including respective light emitting elements, first optical sensors disposed on the substrate to be located between pixels located in the first active area, and including respective first photoelectric conversion elements, second optical sensors disposed on the substrate to be located between pixels located in the second active area, and including respective second photoelectric conversion elements, a light blocking member disposed above at least the second photoelectric conversion elements, and completely covering the second photoelectric conversion elements, and first color filters and second color filters disposed on the light blocking member, and overlapping each other above the second photoelectric conversion elements.

In an embodiment, the first color filters and the second color filters may completely cover the second photoelectric conversion elements.

In an embodiment, the first color filters may be red color filters, and the second color filters may be blue color filters.

In an embodiment, the display device may further include third color filters disposed on the light blocking member and overlapping the first color filters and the second color filters above the second photoelectric conversion elements.

In an embodiment, the third color filters may be green color filters.

In an embodiment, the third color filters may completely cover the second photoelectric conversion elements.

In an embodiment, the light blocking member may be disposed in the first active area and the second active area and include first openings exposing at least a part of each of the light emitting elements and second openings exposing at least a part of each of the first photoelectric conversion elements.

In an embodiment, the pixels may include first color pixels, second color pixels, and third color pixels.

In an embodiment, the display device may further include first color filters disposed in first openings of a first group exposing light emitting elements of the first color pixels among the first openings, second color filters disposed in first openings of a second group exposing light emitting elements of the second color pixels among the first openings, and third color filters disposed in the second openings and first openings of a third group exposing light emitting elements of the third color pixels among the first openings.

In an embodiment, the first active area may be located at a center of an active area including the first active area and the second active area, and the second active area may be located at an edge of the active area.

A display device according to embodiments may include a first optical sensor disposed in a first active area and including a first photoelectric conversion element, and a second optical sensor disposed in a second active area and including a second photoelectric conversion element. Further, the display device may include a light blocking member and first and second color filters disposed above the second photoelectric conversion element to overlap each other.

In accordance with embodiments, it is possible to effectively block external light from being incident on the second photoelectric conversion element. Accordingly, it is possible to effectively sense noise generated from a display panel using the second optical sensor and improve the performance of a light sensing unit (for example, a fingerprint sensor) including the first optical sensor and the second optical sensor.

However, effects according to the embodiments of the present disclosure are not limited to those exemplified above and various other effects are incorporated herein.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to an embodiment;

FIG. 2 is a block diagram of a display device according to an embodiment;

FIG. 3 is a cross-sectional view showing a schematic cross section of the active area of the display device according to an embodiment, and a method for sensing a fingerprint of a finger;

FIG. 4 is a cross-sectional view showing a schematic cross section of the active area of the display device according to an embodiment, and a method for sensing a fingerprint of the finger;

FIG. 5 is a circuit diagram of the pixel and the optical sensor according to an embodiment;

FIG. 6 is a plan view showing the arrangement structure of the pixels, the optical sensors, and the color filters according to an embodiment;

FIG. 7 is a plan view showing the pixels, the optical sensors, and the light blocking member according to an embodiment;

FIG. 8 is a cross-sectional view showing an example of a cross section taken along line I-I′ of FIGS. 6 and 7;

FIG. 9 is a cross-sectional view showing an example of a cross section taken along line II-II′ of FIGS. 6 and 7;

FIG. 10 is a plan view illustrating the arrangement structure of the pixels, the optical sensors, and the color filters according to an embodiment;

FIG. 11 is a cross-sectional view showing an example of a cross section taken along line III-III′ of FIG. 10; and

FIG. 12 is a graph showing light transmittances of light blocking layers according to embodiments.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art.

It will also be understood that when an element or a layer is referred to as being “on” another element or layer, it can be directly on the other element or layer, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. Similarly, the second element could also be termed the first element.

As used herein, the word “or” means logical “or” so that, unless the context indicates otherwise, the expression “A, B, or C” means “A and B and C,” “A and B but not C,” “A and C but not B,” “B and C but not A,” “A but not B and not C,” “B but not A and not C,” and “C but not A and not B.”

Features of each of various embodiments of the present disclosure may be partially or entirely combined with each other and may technically variously interwork with each other, and respective embodiments may be implemented independently of each other or may be implemented together in association with each other.

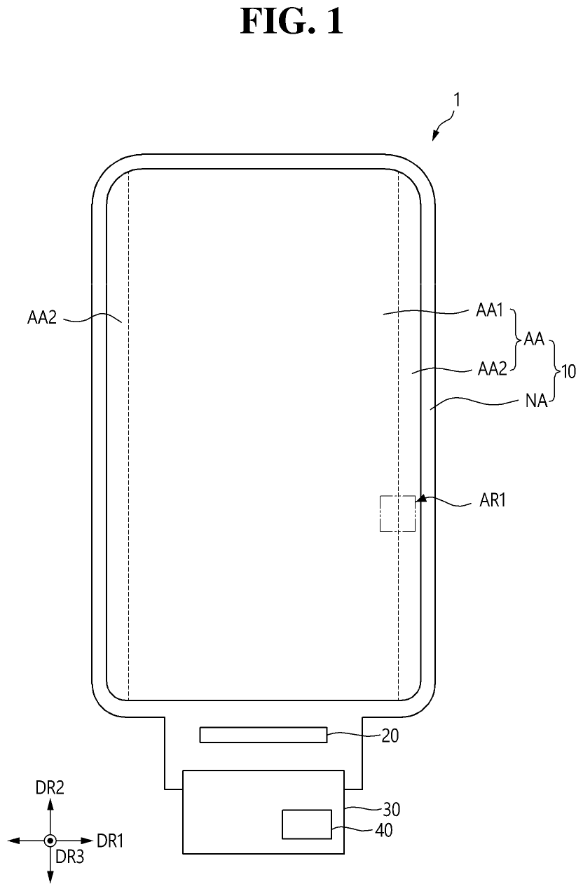

FIG. 1 is a plan view illustrating a display device 1 according to an embodiment.

In FIG. 1, a first direction DR1, a second direction DR2, and a third direction DR3 are indicated. The first direction DR1 may be a direction parallel to one side of the display device 1 in plan view and may be, for example, a horizontal direction of the display device 1. The second direction DR2 may be a direction parallel to the other side in contact with one side of the display device 1 in plan view and may be, for example, a vertical direction of the display device 1. The third direction DR3 may be a thickness direction (or height direction) of the display device 1. However, a direction mentioned in the following embodiments may refer to a relative direction, and the embodiments are not limited thereto.

Further, in the embodiments, the term “above” or “top surface” expressed with respect to the third direction DR3 may refer to a display surface side of a display panel 10, and the term “below,” “bottom surface,” or “rear surface” may refer to a side opposite to the display surface of the display panel 10. However, according to the direction facing the display panel 10 or the display device 1 including the same, the defined direction may be changed to the opposite direction or the like.

Referring to FIG. 1, the display device 1 may be one of various electronic devices providing a display surface on which an image is displayed. For example, the display device 1 may one of various electronic devices including a mobile phone, a smart phone, a tablet personal computer (PC), a mobile communication terminal, an electronic notebook, an electronic book, a personal digital assistant (PDA), a portable multimedia player (PMP), a navigation device, an ultra-mobile PC (UMPC), a television, a game console, a wrist watch type electronic device, a head-mounted display, a personal computer monitor, a laptop computer, a car dashboard, a digital camera, a camcorder, an external billboard, an electric billboard, various medical devices, various inspection devices, various home appliances including a display area such as a refrigerator or a washing machine, an Internet-of-Things (IoT) device, and the like. A typical example of the display device 1 to be described later may be a smart phone, a tablet PC, or a laptop computer, but the display device 1 according to the embodiments is not limited thereto.

The display device 1 may include a display panel 10, a driving circuit 20, a circuit board 30, and a read-out circuit 40 (e.g., a read-out IC).

The display panel 10 may include an active area AA and a non-active area NA. In an embodiment, the display panel 10 may be formed to be partially or entirely flexible, and may be transformed to be folded, bent, or rolled in at least one portion. For example, the display panel 10 may be folded or bent in the non-active area NA, so that a part of the non-active area NA on which the driving circuit 20 or the like is mounted may be positioned on the opposite side (for example, the rear surface side of the display device 1) of the display surface.

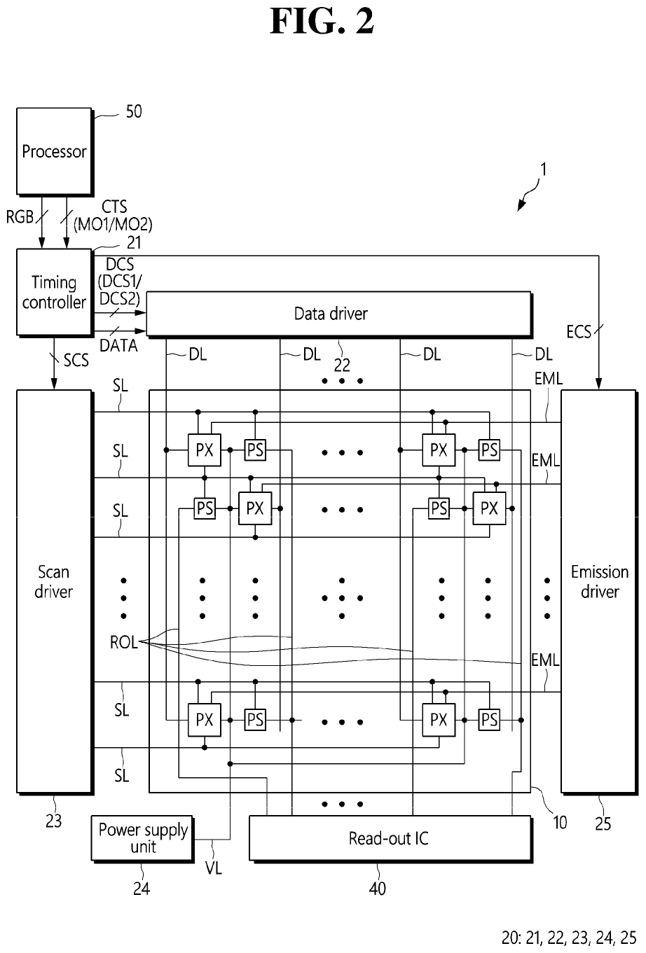

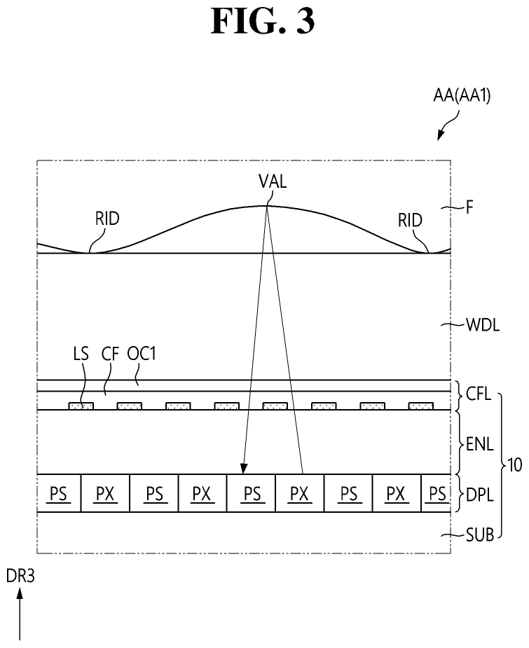

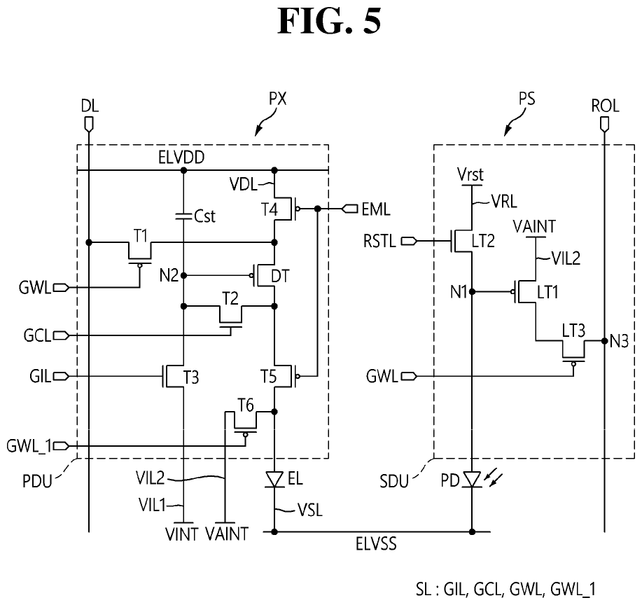

The active area AA may include a display area. For example, the active area AA may completely overlap the display area. Pixels (for example, pixels PX of FIG. 2 or 3) for displaying an image may be disposed in the active area AA (or the display area). Each pixel PX may include a light emitting element (for example, a light emitting element EL of FIG. 5).

The active area AA may further include a sensing area that responds to light. For example, the active area AA may further include a sensing area (for example, a light sensing area) for sensing the amount or wavelength of incident light. In an embodiment, the sensing area may include a fingerprint sensing area for sensing a user's fingerprint using optical sensors.

In an embodiment, the sensing area may overlap the display area. For example, the sensing area may be a part of the display area or may be substantially the same area as the display area. In this case, the sensing area may be a part of the active area AA, or may be the entire active area AA.

Optical sensors (for example, optical sensors PS of FIG. 2 or 3) that respond to light may be disposed in the sensing area. Each optical sensor may include a photoelectric conversion element (for example, a photoelectric conversion element PD of FIG. 5). The photoelectric conversion element may sense incident light and convert it into an electrical signal.

In embodiments, the active area AA may include a first active area AA1 and a second active area AA2. The pixels and the optical sensors may be disposed in the first active area AA1 and the second active area AA2.

The first active area AA1, which is a part of the active area AA, may be a region located at least at the center of the active area AA, for example. The second active area AA2, which is the other part (for example, the other part except the first active area AA1) of the active area AA, may be a region located at the edge (for example, left edge or right edge) of the active area AA, for example.

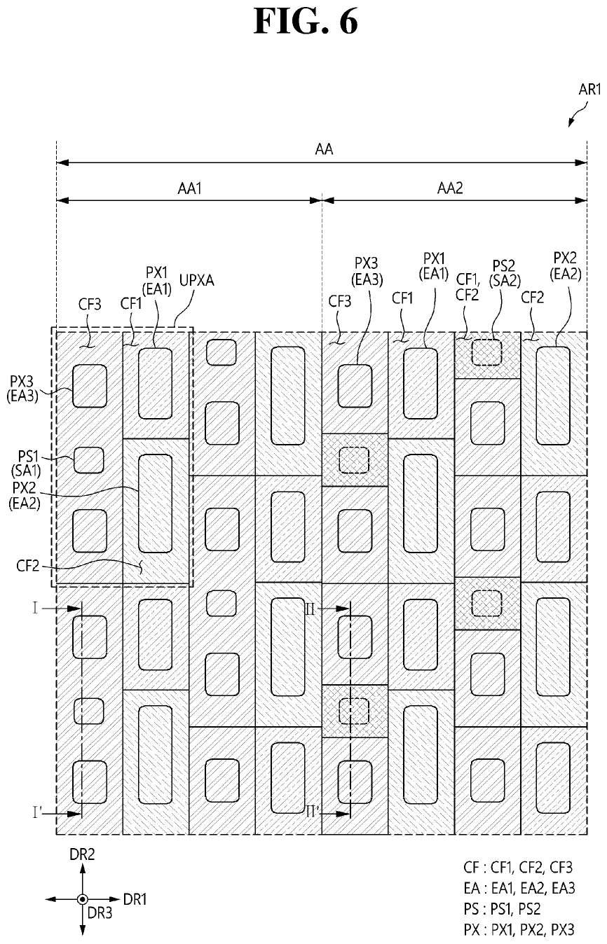

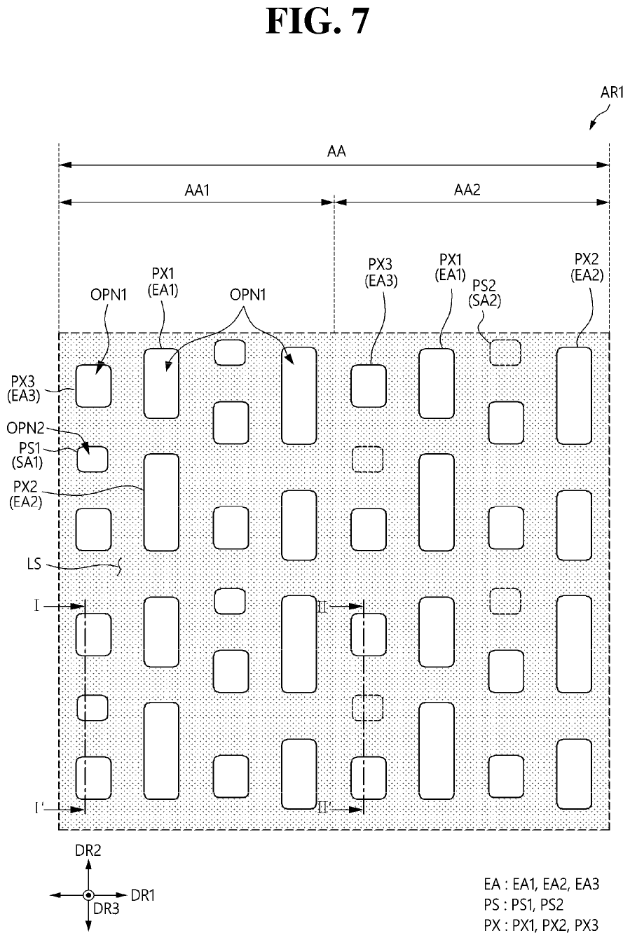

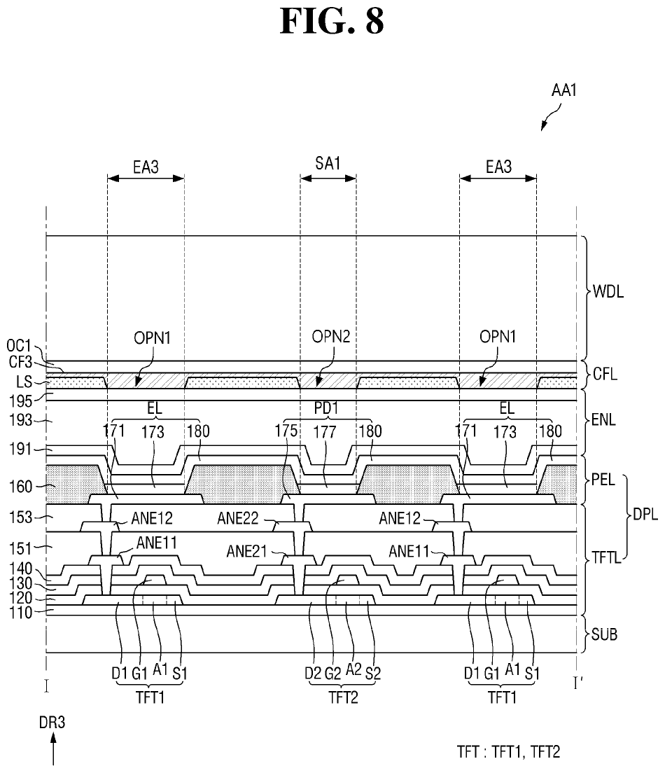

The first active area AA1 may include first optical sensors including respective photoelectric conversion elements. For example, the first active area AA1 may include the first optical sensors (for example, a first optical sensor PS1 of FIGS. 6 and 8) respectively including first photoelectric conversion elements (for example, a first photoelectric conversion element PD1 of FIG. 8) located under a light transmitting portion (for example, a second opening OPN2 of FIGS. 7 and 8) through which at least green light or light of a wavelength band corresponding thereto may transmit. The first optical sensors may output first sensing signals corresponding to incident light, and may sense a user's input (for example, a fingerprint input) provided in the first active area AA1 using the first sensing signals.

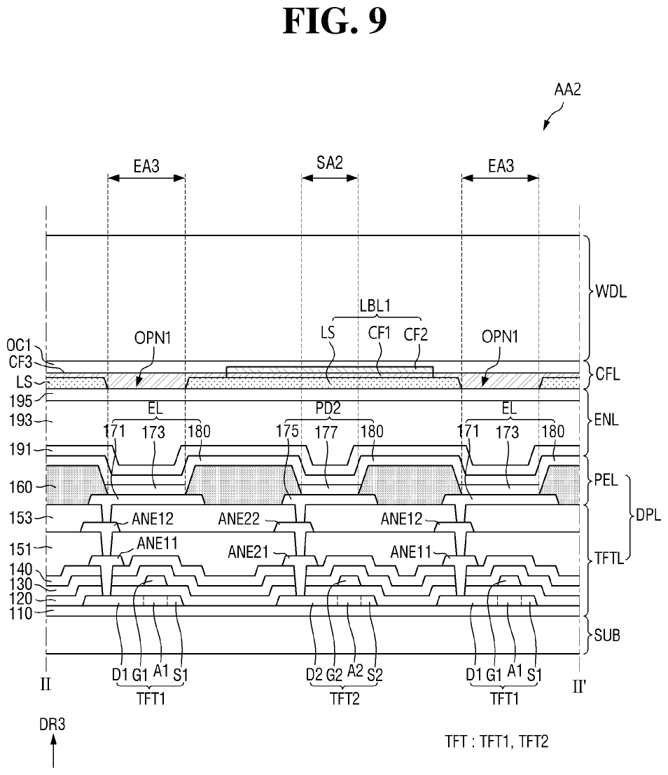

The second active area AA2 may include second optical sensors including respective photoelectric conversion elements located under a light blocking portion that substantially blocks transmission of external light. For example, the second active area AA2 may include the second optical sensors (for example, a second optical sensor PS2 of FIGS. 6 and 9) respectively including second photoelectric conversion elements (for example, a second photoelectric conversion element PD2 of FIG. 9) located under a light blocking member (for example, a light blocking member LS of FIGS. 7 and 9) and color filters of at least two colors (for example, a first color filter CF1 and a second color filter CF2 of FIGS. 6 and 9). The second optical sensors may output second sensing signals corresponding to noise caused by electrical signals (for example, driving signals of the display panel 10) or internal light generated from the display panel 10. In an embodiment, noise included in the first sensing signals may be removed or reduced (for example, subtracted) using the second sensing signals. Accordingly, the performance of the light sensing unit (for example, a fingerprint sensor) including the first optical sensors and the second optical sensors may be improved. For example, in sensing a fingerprint input provided in the first active area AA1 based on the first sensing signals, noise included in the first sensing signals is removed or reduced using the second sensing signals, which makes it possible to more accurately sense the user's fingerprint.

The non-active area NA may include a non-display area, and may be located around the active area AA. The non-active area NA may be located on at least one side of the active area AA, and may partially or entirely surround the active area AA. In an embodiment, the non-active area NA may be a bezel area. Lines, pads, or the driving circuit 20 electrically connected to the pixels or the optical sensors of the active area AA may be disposed in the non-active area NA.

The driving circuit 20 may be electrically connected to the pixels and the optical sensors of the active area AA to drive the pixels and the optical sensors. For example, the driving circuit 20 may generate driving signals or power voltages for driving the pixels and the optical sensors, and may output the driving signals or the power voltages to the pixels and the optical sensors. For example, the driving circuit 20 may include at least one of a gate driving circuit (or a part of the gate driving circuit) including a scan driver or a source driving circuit (or a part of the source driving circuit) including a data driver.

The driving circuit 20 may be formed as an integrated circuit (IC) and mounted on the display panel 10, or may be mounted on the circuit board 30 connected to the display panel 10. In an embodiment, the driving circuit 20 may be provided outside the active area AA. In another embodiment, at least a part of the driving circuit 20 (for example, at least a part of the scan driver) may be provided inside the active area AA, and may be formed together with pixels.

The circuit board 30 may be connected to or attached to one end of the display panel 10. For example, the circuit board 30 may be attached to one end of the display panel 10 using an anisotropic conductive film (ACF). Lead lines of the circuit board 30 may be electrically connected to a pad unit of the display panel 10. In an embodiment, the circuit board 30 may be a flexible film such as a flexible printed circuit board (FPCB) or a chip on film (COF).

The read-out circuit 40 may be electrically connected to the optical sensors disposed in the active area AA. The read-out circuit 40 may receive the electrical signal corresponding to the current flowing through the optical sensors. The read-out circuit 40 may convert the electrical signal received from the optical sensors and transmit it to the processor (for example, the processor provided in a host device or the display device 1) connected to the read-out circuit 40, or may execute a designated function based on the electrical signal.

In an embodiment, the read-out circuit 40 may be formed as an integrated circuit (IC) and attached on the circuit board 30 by a chip on film (COF) method, but the embodiments are not limited thereto. For example, the read-out circuit 40 may be attached to the non-active area NA of the display panel 10 by a chip on glass (COG) method, a chip on plastic (COP) method, or an ultrasonic bonding method.

FIG. 2 is a block diagram of a display device according to an embodiment.

Referring to FIG. 2 in addition to FIG. 1, the display device 1 may include the display panel 10, the driving circuit 20, the read-out circuit 40, and a processor 50. Although FIG. 2 discloses an embodiment in which the processor 50 is provided in the display device 1, the embodiments are not limited thereto. For example, the processor 50 may be provided in the host device connected to the display device 1.

The display panel 10 may include the pixels PX and the optical sensors PS disposed in the active area AA, scan lines SL and power voltage lines VL connected (for example, electrically connected) to the pixels PX and the optical sensors PS, data lines DL and emission control lines EML connected to the pixels PX, and read-out lines ROL connected to the optical sensors PS.

Each pixel PX may be connected to at least one scan line SL, any one data line DL, any one emission control line EML, and at least one power voltage line VL. In embodiments, the pixels PX may be disposed in the first active area AA1 and the second active area AA2 of FIG. 1.

Each optical sensor PS may be connected to at least one scan line SL, any one read-out line ROL, and at least one power voltage line VL. In embodiments, the optical sensors PS may include the first optical sensors located in the first active area AA1 of FIG. 1 and the second optical sensors located in the second active area AA2 of FIG. 1. In an embodiment, the optical sensors PS may be disposed between the pixels PX, and may be formed inside the display panel 10 together with the pixels PX. For example, the first optical sensors may be formed or disposed between the pixels PX located in the first active area AA1, and the second optical sensors may be formed or disposed between the pixels PX located in the second active area AA2.

The scan lines SL may connect the pixels PX and the optical sensors PS to the scan driver 23. The scan lines SL may transmit or provide scan signals outputted from the scan driver 23 to the pixels PX and the optical sensors PS.

The data lines DL may connect the pixels PX to the data driver 22. The data lines DL may transmit or provide respective data signals outputted from the data driver 22 to the pixels PX.

The emission control lines EML may connect the pixels PX to an emission control driver 25. The emission control lines EML may transmit or provide emission control signals outputted from the emission control driver 25 to the pixels PX.

The read-out lines ROL may connect the optical sensors PS to the read-out circuit 40. The read-out lines ROL may transmit or provide an electrical signal (for example, sensing currents or sensing signals) generated according to a photoelectric current outputted from the optical sensors PS to the read-out circuit 40. Accordingly, the read-out circuit 40 may sense a user's input (for example, a fingerprint input).

The power voltage lines VL may connect the pixels PX and the optical sensors PS to a power supply unit 24. For example, the power voltage lines VL may transmit or provide a first power voltage ELVDD, a second power voltage ELVSS, or other power voltages generated or outputted from the power supply unit 24 to the pixels PX and the optical sensors PS. FIG. 2 illustrates that one power voltage line VL is provided in the display panel 10, but the power voltage lines VL corresponding to the type or number of power voltages required to drive the pixels PX and the optical sensors PS may be provided or formed in the display panel 10.

The driving circuit 20 may include a data driver 22 for driving the pixels PX, a scan driver 23 for driving the pixels PX and the optical sensors PS, and a timing controller 21 for controlling driving timing of the data driver 22 and the scan driver 22. In an embodiment, the driving circuit 20 may further include the power supply unit 24 for generating or transmitting power voltages for driving the pixels PX and the optical sensors PS, or the emission control driver 25 for driving the pixels PX.

The timing controller 21 may receive an image signal RGB and control signals CTS from the processor 50. The timing controller 21 may output image data DATA, a data control signal DCS, a scan control signal SCS, and an emission control driving signal ECS based on the image signal RGB and the control signals CTS. The image data DATA and the data control signal DCS may be supplied to the data driver 22. The scan control signal SCS and the emission control driving signal ECS may be supplied to the scan driver 23 and the emission control driver 25, respectively.

In an embodiment, the control signals CTS may include a first mode control signal MO1 and a second mode control signal MO2. The timing controller 21 may generate a first data control signal DCS1 when the first mode control signal MO1 is supplied, and may generate a second data control signal DCS2 when the second mode control signal MO2 is supplied.

The data driver 22 may generate data signals corresponding to the image data DATA, and may output the data signals to the data lines DL. For example, the data driver 22 may convert the image data DATA into analog data voltages and may output them to the data lines DL. The data signals may be supplied to the pixels PX through the data lines DL.

The scan driver 23 may generate scan signals in response to the scan control signal SCS, and may output the scan signals to the scan lines SL. The scan signals may be supplied to the pixels PX and the optical sensors PS through the scan lines SL.

The power supply unit 24 may generate at least one power voltage for driving the pixels PX and the optical sensors PS, and may output the at least one power voltage to at least one power voltage line VL. The at least one power voltage may be supplied to the pixels PX and the optical sensors PS through the power voltage line VL.

The emission control driver 25 may generate emission control signals in response to the emission control driving signal ECS, and may output the emission control signals to the emission control lines EML. The emission control driver 25 may be formed or provided separately from the scan driver 23, or may be formed or provided while being integrated with the scan driver 23.

The read-out circuit 40 may be connected to each optical sensor PS through the read-out line ROL, and may receive the current that may be flowing through each optical sensor PS and sense a user's fingerprint input. The read-out circuit 40 may generate digital sensing data according to the magnitude of the current sensed by each optical sensor PS and transmit it to the processor 50, and the processor 50 may analyze the digital sensing data to determine whether or not a preset fingerprint matches the user's fingerprint by comparing both fingerprints. When the preset fingerprint and the digital sensing data transmitted from the read-out circuit 40 are the same, preset functions may be performed.

The processor 50 may supply the image signal RGB and the control signals CTS supplied from the outside to the timing controller 21. The processor 50 may further include a graphic processing unit (hereinafter, referred to as GPU) that provides graphics for the image signal RGB. The image signal RGB, which is an image source that has been subjected to graphic processing in the GPU, may be provided to the timing controller 21. The image signal RGB may have a frequency of 120 Hz or 30 Hz, for example.

The control signals CTS outputted from the processor 50 may include the first mode control signal MO1, the second mode control signal MO2, a clock signal, an enable signal, and the like. The first mode control signal MO1 may include a display mode signal for displaying a normal image. The second mode control signal MO2 may include a sensing mode signal for sensing a user's fingerprint or the like. In an embodiment, the second mode control signal MO2 may be a signal that causes at least some pixels PX (for example, green pixels) to emit light during a period in which the sensing mode is executed. Accordingly, a user's fingerprint or the like may be sensed while using the pixels PX as a light source.

The processor 50 may supply the first mode control signal MO1 to the timing controller 21 in order to display an image on the display panel 10. The processor 50 may supply the second mode control signal MO2 to the timing controller 21 in order to sense a user's fingerprint or the like. The timing controller 21 may drive the pixels PX and the optical sensors PS of the display panel 10 in response to the second mode control signal MO2.

FIG. 3 is a cross-sectional view showing a schematic cross section of the active area AA of the display device 1 according to an embodiment, and a method for sensing a fingerprint of a finger F. FIG. 3 illustrates the method for sensing the fingerprint of the finger F located on the first active area AA1.

Referring to FIG. 3 in addition to FIGS. 1 and 2, the display device 1 may include the display panel 10, and a window WDL disposed on the display panel 10. The display panel 10 may include a substrate SUB, a display layer DPL disposed on the substrate SUB, and an encapsulation layer ENL and a color filter layer CFL disposed on the display layer DPL.

The display layer DPL may include the pixels PX and the optical sensors PS disposed on the substrate SUB. The substrate SUB may include the active area AA and the non-active area NA, and the pixels PX and the optical sensors PS may be disposed on the substrate SUB to be located in the active area AA.

For simplicity, FIG. 3 illustrates an embodiment in which the pixels PX and the optical sensors PS are alternately arranged one by one along at least one direction (for example, the first direction DR1 or the second direction DR2 intersecting the third direction DR3), but the arrangement structure, number, or resolution of the pixels PX and the optical sensors PS may be variously changed according to embodiments.

The encapsulation layer ENL may be disposed on the display layer DPL to cover at least the pixels PX and the optical sensors PS. The encapsulation layer ENL may protect the pixels PX and the optical sensors PS.

The color filter layer CFL may include the light blocking member LS and the color filter CF located above the pixels PX and the optical sensors PS. In an embodiment, the color filter layer CFL may further include a first overcoat layer OC1 covering the light blocking member LS and the color filter CF.

The light blocking member LS may be disposed above the display layer DPL (for example, above the encapsulation layer ENL covering the display layer DPL) to be located between the pixels PX and the optical sensors PS and may be disposed at the boundary thereof. The light blocking member LS may include openings exposing at least a part of the pixels PX. Further, the light blocking member LS may include openings exposing at least a part of some of the optical sensors PS (for example, the first optical sensors located in the first active area AA1). In embodiments, the light blocking member LS may be disposed above some others of the optical sensors PS (for example, the second optical sensors located in the second active area AA2) to block external light from being incident on the some others of the optical sensors PS.

The color filter CF may be located at least in the active area AA to overlap the pixels PX and the optical sensors PS. The color filter CF may be disposed above each pixel PX to correspond to the color (or wavelength band) of light to be emitted from the corresponding pixel PX. In an embodiment, the color filter CF of a specific color (for example, a green color filter) may be disposed above the optical sensors PS located in the first active area AA1, and the color filters CF of at least two colors (for example, red and blue color filters) may be disposed above the optical sensors PS located in the second active area AA2.

The window WDL may be disposed above the display panel 10 to protect the display panel 10. For example, the window WDL may be provided on the display surface of the display panel 10.

When the user's finger F (for example, a part of the finger F including a fingerprint region) is in contact with the top surface of the window WDL, the light emitted from the pixels PX of the display panel 10 may be reflected from ridges RID of the finger F and valleys VAL between the ridges RID. The portions corresponding to the ridges RID of the finger F may be in contact with the top surface of the window WDL, whereas the portions corresponding to the valleys VAL of the finger F may not be in contact with the window WDL. Accordingly, the top surface of the window WDL may be in contact with air at the portions corresponding to the valleys VAL of the finger F.

Since the refractive index of the finger F is different from the refractive index of air, the amount of light reflected from the ridges RID and the amount of light reflected from the valleys VAL may be different. Accordingly, the shape of the fingerprint formed on the finger F may be obtained based on the difference in the amount of light reflected from the finger F and incident on each of the optical sensors PS. For example, each optical sensor PS may output the electrical signal (for example, the photoelectric current or the sensing signal corresponding to the photoelectric current) corresponding to the amount of received light, and may identify the shape of the fingerprint formed on the finger F using the electrical signals outputted from the optical sensors PS.

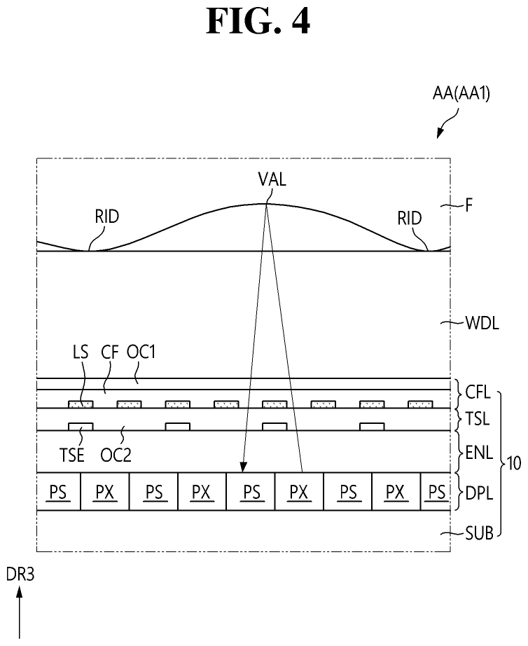

FIG. 4 is a cross-sectional view showing a schematic cross section of the active area AA of the display device 1 according to an embodiment, and a method for sensing a fingerprint of the finger F.

Referring to FIG. 4, the display device 1 may further include a touch sensor layer TSL. In an embodiment, the touch sensor layer TSL may be provided inside the display panel 10. For example, the touch sensor layer TSL may be disposed between the encapsulation layer ENL and the color filter layer CFL, and may be formed directly on the encapsulation layer ENL. The position of the touch sensor layer TSL is not limited thereto, and may vary according to embodiments.

The touch sensor layer TSL may include sensing patterns TSE (for example, touch electrodes for generating an electrical signal according to a touch input) for sensing a user's touch input, and a second overcoat layer OC2 covering the sensing patterns TSE. The type, structure, and material of the sensing patterns TSE disposed on the touch sensor layer TSL may be variously changed according to embodiments.

The display device 1 may sense a user's touch input provided to the display surface side (for example, the top surface of the window WDL) using the touch sensor layer TSL. The other components of the display device 1 according to the embodiment of FIG. 4 and the method for sensing a fingerprint of the finger F using the optical sensors PS are substantially similar to or the same as those of the display device 1 according to the embodiment of FIG. 3, so that a detailed description thereof will be omitted.

FIG. 5 is a circuit diagram of the pixel PX and the optical sensor PS according to an embodiment.

FIG. 5 discloses an embodiment in which the scan lines SL connected to each pixel PX include a scan initialization line GIL, a scan control line GCL, a first scan line GWL, and a first_first scan line GWL_1. In an embodiment, the scan lines SL may further include a reset control line RSTL connected to at least one optical sensor PS.

In an embodiment, the reset control line RSTL may be integrated with one of the scan initialization line GIL, the scan control line GCL, and the first_first scan line GWL_1, or may be separated from the scan initialization line GIL, the scan control line GCL, and the first_first scan line GWL_1 and receive a separate reset signal. In an embodiment, the reset signal may be sequentially applied to the optical sensors PS divided in units of at least one row or in units of a block, or may be simultaneously applied to the optical sensors PS disposed in the active area AA. For example, the optical sensors PS may be sequentially reset or simultaneously reset.

In an embodiment, the optical sensor PS may be driven using at least one of the scan signals transmitted to the scan lines SL for driving the pixel PX. For example, the optical sensor PS may be driven using a first scan signal transmitted to the first scan line GWL.

Referring to FIG. 5, the pixel PX may include the light emitting element EL and a pixel driver PDU (for example, a pixel circuit) connected to the light emitting element EL.

The light emitting element EL may be connected between the second driving voltage line VSL to which the second power voltage ELVSS is applied and a pixel circuit PXC. The light emitting element EL, which is a light source of the pixel PX, may emit light in response to the driving current supplied from the pixel driver PDU. As the driving current increases, the light emitting element EL may emit light with a high luminance.

In an embodiment, the light emitting element EL may be an organic light emitting diode, but is not limited thereto. For example, the light emitting element EL may be an inorganic light emitting element, a quantum dot light emitting element, or another type of light emitting element.

The pixel driver PDU may control the light emitting timing and luminance of the light emitting element EL by controlling the driving current supplied to the light emitting element EL. The pixel driver PDU may include a driving transistor DT, switch elements, and a capacitor Cst. In an embodiment, the switch elements may include first to sixth transistors T1, T2, T3, T4, T5, and T6.

The driving transistor DT may include a gate electrode, a first electrode, and a second electrode. One of the first electrode and the second electrode may be a source electrode and the other one may be a drain electrode. The driving transistor DT may control a drain-source current (hereinafter, referred to as “driving current”) flowing between the first electrode and the second electrode according to a voltage of the data signal applied to the gate electrode.

The first transistor T1 may include the gate electrode connected to the first scan line GWL, the first electrode connected to the data line DL, and the second electrode connected to the first electrode of the driving transistor DT. The first transistor T1 may be turned on by the first scan signal supplied to the first scan line GWL to connect the first electrode of the driving transistor DT to the data line DL. When the first transistor T1 is turned on, the voltage of the data signal supplied to the data line DL may be applied to the first electrode of the driving transistor DT.

The second transistor T2 may include the gate electrode connected to the scan control line GCL, the first electrode connected to the second electrode of the driving transistor DT, and the second electrode connected to the gate electrode (or the second node N2) of the driving transistor DT. The second transistor T2 may turned on by the scan control signal supplied to the scan control line GCL to connect the gate electrode of the driving transistor DT to the second electrode of the driving transistor DT. When the gate electrode of the driving transistor DT is connected to the second electrode thereof, the driving transistor DT may be driven as a diode.

The third transistor T3 may include the gate electrode connected to the scan initialization line GIL, the first electrode connected to the gate electrode of the driving transistor DT, and the second electrode connected to the first initialization voltage line VIL1. The third transistor T3 may be turned on by the scan initialization signal supplied to the scan initialization line GIL to connect the gate electrode of the driving transistor DT to the first initialization voltage line VIL1. When the third transistor T3 is turned on, the first initialization voltage VINT of the first initialization voltage line VIL1 may be applied to the gate electrode of the driving transistor DT.

The fourth transistor T4 may include the gate electrode connected to the emission control line EML, the first electrode connected to the first driving voltage line VDL, and the second electrode connected to the first electrode of the driving transistor DT. The fourth transistor T4 may be turned on by the emission control signal supplied to the emission control line EML to connect the first electrode of the driving transistor DT to the first driving voltage line VDL to which the first power voltage ELVDD is applied. When the fourth transistor T4 is turned on, the first power voltage ELVDD may be applied to the first electrode of the driving transistor DT.

The fifth transistor T5 may include the gate electrode connected to the emission control line EML, the first electrode connected to the second electrode of the driving transistor DT, and the second electrode connected to the light emitting element EL. The fifth transistor T5 may be turned on by the emission control signal supplied to the light emission control line EML to connect the driving transistor DT to the light emitting element EL. When both the fourth transistor T4 and the fifth transistor T5 are turned on, the driving current according to the voltage of the gate electrode of the driving transistor DT may flow through the light emitting element EL.

The sixth transistor T6 may include the gate electrode connected to the first_first scan line GWL_1, the first electrode connected to the anode electrode of the light emitting element EL, and the second electrode connected to a second initialization voltage line VIL2. The sixth transistor T6 may turned on by a first_first scan signal supplied to the first_first scan line GWL_1 to connect the anode electrode of the light emitting element EL to a second initialization voltage line VIL2. When the sixth transistor T6 is turned on, a second initialization voltage VAINT of the second initialization voltage line VIL2 may be applied to the anode electrode of the light emitting element EL.

The capacitor Cst may be connected between the gate electrode of the driving transistor DT and the first driving voltage line VDL. The capacitor Cst may store the voltage corresponding to the voltage of the data signal applied to the gate electrode of the driving transistor DT.

An active layer (for example, a semiconductor pattern including a channel region) of the driving transistor DT and each of the first to sixth transistors T1, T2, T3, T4, T5, and T6 may be formed of one of polysilicon, amorphous silicon, and an oxide semiconductor. In an embodiment, the active layer of each of the driving transistor DT, the first transistor T1, and the fourth to sixth transistors T4, T5, and T6 may be made of polysilicon. The active layer of each of the second transistor T2 and the third transistor T3 may be formed of an oxide semiconductor. In this case, the driving transistor DT, the first transistor T1, and the fourth to sixth transistors T4, T5, and T6 may be formed of a P-type MOSFET, and the second transistor T2 and the third transistor T3 may be formed of an N-type MOSFET.

The optical sensor PS may include the photoelectric conversion element PD and a sensing driver SDU (for example, an optical sensor circuit) for controlling a sensing current according to the photoelectric current of the photoelectric conversion element PD.

The photoelectric conversion element PD may be connected between the sensing driver SDU and the second driving voltage line VSL. The photoelectric conversion element PD may be a photodiode including an anode electrode, a cathode electrode, and a photoelectric conversion layer disposed between the anode electrode and the cathode electrode. The photoelectric conversion element PD may convert externally incident light into an electrical signal. In an embodiment, the photoelectric conversion element PD may be an inorganic photodiode or a phototransistor formed of a PN type or PIN type inorganic material. Alternatively, the photoelectric conversion element PD may also be an organic photodiode including an electron donating material generating donor ions and an electron accepting material generating acceptor ions.

When the photoelectric conversion element PD is exposed to external light, photocharges may be generated, and the generated photocharges may be accumulated in the anode electrode of the photoelectric conversion element PD. In this case, the voltage of a first node N1 electrically connected to the anode electrode of the photoelectric conversion element PD may increase. When the photoelectric conversion element PD and the read-out line ROL are connected according to the turn-on of the first and third sensing transistors LT1 and LT3, a sensing voltage may be accumulated at the third node N3 between the read-out line ROL and the third sensing transistor LT3 in proportion to the voltage of the first node N1 in which the electric charges are accumulated.

The sensing driver SDU may include the sensing transistors for controlling the sensing current generated by the photoelectric conversion element PD. For example, the sensing driver SDU may include first to third sensing transistors LT1, LT2, and LT3.

The first sensing transistor LT1 may include the gate electrode connected to the first node N1, the first electrode connected to the second initialization voltage line VIL2, and the second electrode connected to the first electrode of the third sensing transistor LT3. The first sensing transistor LT1 may be turned on by the voltage of the first node N1 to connect the second initialization voltage line VIL2 to the first electrode of the third sensing transistor LT3. The first sensing transistor LT1 may be a source follower amplifier that generates a source-drain current in proportion to the amount of electric charges of the first node N1 inputted to the gate electrode thereof. FIG. 5 discloses an embodiment in which the first electrode of the first sensing transistor LT1 is connected to the second initialization voltage line VIL2, but the embodiments are not limited thereto. For example, the first electrode of the first sensing transistor LT1 may be connected to the first driving voltage line VDL or the first initialization voltage line VIL1.

The second sensing transistor LT2 may include the gate electrode connected to the reset control line RSTL, the first electrode connected to the reset voltage line VRL, and the second electrode connected to the first node N1. The second sensing transistor LT2 may be turned on by the reset control signal supplied to the reset control line RSTL to connect the reset voltage line VRL to which the reset voltage Vrst is applied to the first node N1. When the second sensing transistor LT2 is turned on, the voltage of the first node N1 may be initialized by the reset voltage Vrst.

The third sensing transistor LT3 may include the gate electrode connected to the first scan line GWL, the first electrode connected to the second electrode of the first sensing transistor LT1, and the second electrode connected to the read-out line ROL. The third sensing transistor LT3 may be turned on by the first scan signal supplied to the first scan line GWL to connect the second electrode of the first sensing transistor LT1 and the read-out line ROL. When the third sensing transistor LT3 is turned on, the electrical signal corresponding to the photoelectric current flowing through the optical sensor PS may be transmitted to the read-out circuit 40 through the read-out line ROL.

An active layer of each of the first to third sensing transistors LT1, LT2, and LT3 may be formed of one of polysilicon, amorphous silicon, and an oxide semiconductor. In an embodiment, the active layer of the first sensing transistor LT1 and the third sensing transistor LT3 may be made of polysilicon. The active layer of the second sensing transistor LT2 may be formed of an oxide semiconductor. In this case, the first sensing transistor LT1 and the third sensing transistor LT3 may be formed of a P-type MOSFET, and the second sensing transistor LT2 may be formed of an N-type MOSFET.

FIG. 6 is a plan view showing the arrangement structure of the pixels PX, the optical sensors PS, and the color filters CF according to an embodiment. FIG. 7 is a plan view showing the pixels PX, the optical sensors PS, and the light blocking member LS according to an embodiment. FIGS. 6 and 7 illustrate the pixels PS, the optical sensors PS, the color filters CF, and the light blocking member LS that are disposed in a part of the active area AA corresponding to a first area AR1 of FIG. 1.

Referring to FIGS. 6 and 7 in addition to FIGS. 1 to 5, the pixels PX may include first color pixels (also referred to as “first pixels”) PX1 emitting light of a first color, second color pixels (also referred to as “second pixels”) PX2 emitting light of a second color, and third color pixels (also referred to as “third pixels”) PX3 emitting light of a third color. In an embodiment, the first color pixels PX1 may be red pixels emitting red light, the second color pixels PX2 may be blue pixels emitting blue light, and the third color pixels PX3 may be green pixels emitting green light. However, the embodiments are not limited thereto, and the type and configuration of the pixels PX and the color of light emitted from each pixel PX may vary according to embodiments.

In an embodiment, at least one first color pixel PX1, at least one second color pixel PX2, and at least one third color pixel PX3 that are disposed adjacent to each other in one unit pixel area UPXA may constitute one unit pixel. For example, one first color pixel PX1, one second color pixel PX2, and two third color pixels PX3 that are disposed in each unit pixel area UPXA may constitute one unit pixel. Each unit pixel may be defined as minimum unit pixels PX for displaying white light. Various colors may be expressed by adjusting the light emitting ratio of the pixels PX included in each unit pixel.

In an embodiment, in each pixel column, the first color pixels PX1 and the second color pixels PX2 may be alternately arranged, or the third color pixels PX3 may be disposed. In an embodiment, the optical sensors PS (for example, the first optical sensors PS1 or the second optical sensors PS2) may be disposed in each pixel column in which the third color pixels PX3 are disposed. The optical sensors PS may be disposed with a resolution that is the same as that of the pixels PX, or may be disposed with a resolution different from that of the pixels PX. The shape, arrangement structure, resolution, and the like of the pixels PX and the optical sensors PS are not limited to the embodiment illustrated in FIG. 6, and may be variously changed according to embodiments.

The pixels PX may include respective emission areas EA (or light emitting units including the respective light emitting elements EL). For example, the first color pixel PX1 may include a first emission area EA1 emitting first light of a first color (for example, red light of a wavelength band of about 600 nm to 750 nm), and the second color pixel PX2 may include a second emission area EA2 emitting second light of a second color (for example, blue light of a wavelength band of about 370 nm to 460 nm). The third color pixel PX3 may include a third emission area EA3 emitting third light of a third color (for example, green light of a wavelength band of about 480 nm to 560 nm).

For simplicity, in FIG. 6, the location of the corresponding pixel PX is displayed with respect to the emission area EA of each pixel PX, but the pixel PX may have an area greater than that of the emission area EA. For example, the pixel area where each pixel PX is disposed or formed may include a pixel circuit area where the pixel driver PDU of the corresponding pixel PX is formed and the emission area EA where the light emitting element EL of the corresponding pixel PX or the like is formed. In an embodiment, the first color pixels PX1, the second color pixels PX2, or the third color pixels PX3 may include the emission areas EA having different sizes (for example, different areas) according to luminous efficiency or white balance of the first color pixels PX1, the second color pixels PX2, or the third color pixels PX3, but embodiments are not limited thereto.

The color filters CF may be disposed on the emission areas EA (or the light emitting units including the respective light emitting elements EL) of the pixels PX and peripheral areas thereof. For example, the first color filter CF1 for selectively transmitting the first light of the first color may be disposed in the first emission area EA1 of the first color pixel PX1, and the second color filter CF2 for selectively transmitting the second light of the second color may be disposed in the second emission area EA2 of the second color pixel PX2. The third color filter CF3 for selectively transmitting the third light of the third color may be disposed in the third emission area EA3 of the third color pixel PX3. In an embodiment, the first color filter CF1, the second color filter CF2, and the third color filter CF3 may be a red color filter, a blue color filter, and a green color filter, respectively.

The first optical sensors PS1 may be disposed in the first active area AA1. For example, the first optical sensors PS1 may be disposed between the pixels PX disposed in the first active area AA1. In an embodiment, the first optical sensors PS1 may be disposed in pixel columns in which the third color pixels PX3 are disposed in the first active area AA1.

The first optical sensors PS1 may include respective first sensing areas SA1. The photoelectric conversion element PD (for example, the first photoelectric conversion element PD1 of FIG. 8) may be disposed in the first sensing area SA1 of each of the first optical sensors PS1.

Each of the first sensing areas SA1 may include a light transmitting portion through which external light may transmit. Each of the first optical sensors PS1 may output the first sensing signal according to the amount of received light (for example, the amount of light incident on the first photoelectric conversion element PD1).

In an embodiment, any one color filter CF may be disposed in the first sensing area SA1 (or a sensing unit including the first photoelectric conversion element PD1) of each of the first optical sensors PS1. For example, the third color filter CF3 may be disposed above the first optical sensor PS1. In this case, the first optical sensor PS1 may sense the third light of the third color, and may output the first sensing signal according to the amount of received light.

In an embodiment, the first optical sensors PS1 may constitute a fingerprint sensor provided in the first active area AA1. For example, each of the first optical sensors PS1 may be a sensing pixel of a fingerprint sensor.

The second optical sensors PS2 may be disposed in the second active area AA2. For example, the second optical sensors PS2 may be disposed between the pixels PX disposed in the second active area AA2. In an embodiment, the second optical sensors PS2 may be disposed in pixel columns in which the third color pixels PX3 are disposed in the second active area AA2.

The second optical sensors PS2 may include respective second sensing areas SA2. The photoelectric conversion element PD (for example, the second photoelectric conversion element PD2 of FIG. 9) may be disposed in the second sensing area SA2 of each of the second optical sensors PS2.

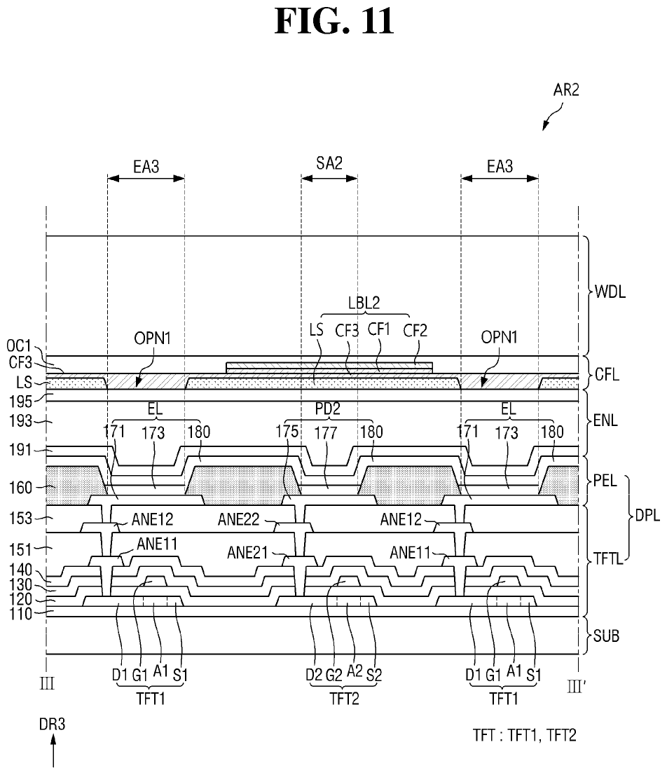

In an embodiment, a light blocking layer (for example, a first light blocking layer LBL1 of FIG. 9 or a second light blocking layer LBL2 of FIG. 11) capable of blocking external light may be provided in each of the second sensing areas SA2. For example, at least an upper portion of the photoelectric conversion element PD may be shielded by the light blocking member LS and the color filter CF so that external light is substantially prevented from being incident on the second optical sensors PS2.

In embodiments, on the second sensing area SA2 (or the sensing unit including the photoelectric conversion element PD) of each of the second optical sensors PS2, the light blocking member LS and the color filters CF of at least two different colors may be disposed to overlap each other. Each of the color filters CF provided in each second sensing area SA2 may be integrally formed with the color filter CF of a specific color provided in at least one adjacent pixel PX, or may be formed separately from the color filter CF provided in the pixels PX.

In an embodiment, the combination of at least two color filters CF disposed in the second sensing area SA2 may be the combination including the color filters CF whose types are the same as those of the color filters CF of the pixels PX and having a light transmittance (for example, a light transmittance of external light) lower than or equal to a reference value. For example, in the second sensing area SA2, the light blocking member LS, the first color filter CF1, and the second color filter CF2 may be disposed above the second optical sensor PS2 to overlap each other. For example, the light blocking member LS, the red color filter, and the blue color filter may be disposed to overlap on the photoelectric conversion element PD of the second optical sensor PS2. Accordingly, the second optical sensor PS2 may be effectively shielded from external light so that the light transmittance of the second sensing area SA2 satisfies a reference value range (for example, 0.0001% or less).

Each of the second optical sensors PS2 may output the second sensing signal (for example, a second sensing current) corresponding to noise caused by an electrical signal or light generated inside the display panel 10. For example, the second optical sensor PS2 may output the second sensing signal corresponding to the noise when noise caused by an electrical signal or internal light of the display panel 10 is introduced.

In an embodiment, the second sensing signal may be used to calibrate the first sensing signal by removing or reducing the noise included in the first sensing signal. For example, by subtracting the second sensing signal from the first sensing signal, the first sensing signal may be calibrated, and the intensity or wavelength of external light may be more accurately sensed. For example, when a fingerprint sensor for sensing a user's fingerprint in the first active area AA1 is configured using the first optical sensors PS1, the second optical sensors PS2 may be reference sensing pixels or noise sensing pixels that are utilized to increase the sensitivity of the fingerprint sensor. In this case, the display device 1 may include a calibration unit (or a noise removal unit) for receiving the first sensing signal and the second sensing signal (or the digitally converted first sensing signal and second sensing signal), and generating an output sensing signal corresponding to the difference value between the first sensing signal and the second sensing signal.

In an embodiment, the sensing signal corresponding to the difference value between the first sensing signal and the second sensing signal may be outputted from the inside of the read-out circuit 40 of FIG. 2 (for example, an AFE terminal where the first and second sensing signals are received). In another embodiment, the read-out circuit 40 of FIG. 2 may output sensing signals (for example, sensing signals obtained by converting the first sensing signal and the second sensing signal into digital signals) respectively corresponding to the first sensing signal and the second sensing, and the processor (for example, the processor 50 of FIG. 2 or the processor of the host device) for sensing a fingerprint or the like using the sensing signals from the read-out circuit 40 may remove or reduce the noise included in the first sensing signal based on the difference value between the first sensing signal and the second sensing signal.

The light blocking member LS may be located between the pixels PX and in the non-emission area corresponding to the edge, and may be opened to expose the emission areas EA of the pixels PX and the first sensing areas SA1 of the first optical sensors PS1. For example, the light blocking member LS may be disposed in the active area AA including the first active area AA1 and the second active area AA2, and may include first openings OPN1 corresponding to the emission areas EA of the pixel PX and second openings OPN2 corresponding to the first sensing areas SA1 of the first optical sensors PS1. The first openings OPN1 may expose at least a part of the light emitting elements EL (for example, the light emitting elements EL of FIGS. 8 and 9) disposed in the respective emission areas EA. The second openings OPN2 may expose at least a part of the photoelectric conversion elements PD (for example, the first photoelectric conversion element PD1 of FIG. 8) disposed in the respective first sensing areas SA1.

The light blocking member LS may block external light from being incident on the second optical sensors PS2 by covering the second sensing areas SA2 of the second optical sensors PS2. For example, the light blocking member LS may be disposed in the second sensing areas SA2 to cover the photoelectric conversion element PD (for example, the second photoelectric conversion element PD2 of FIG. 9) disposed in the second sensing area SA2 of each of the second optical sensors PS2. For example, the light blocking member LS may be disposed above the photoelectric conversion elements PD in the second sensing areas SA2 to completely cover the photoelectric conversion elements PD disposed in the second sensing areas SA2.

FIG. 8 is a cross-sectional view showing an example of a cross section taken along line I-I′ of FIGS. 6 and 7. FIG. 9 is a cross-sectional view showing an example of a cross section taken along line II-II′ of FIGS. 6 and 7.

Referring to FIGS. 8 and 9 in addition to FIGS. 1 to 7, the substrate SUB, which is a base member (or a base layer) of the display panel 10, may be rigid or flexible. In an embodiment, the substrate SUB may be one of a glass substrate, a quartz substrate, a glass ceramic substrate, a film substrate including a polymeric organic material, and a plastic substrate. In an embodiment, the substrate SUB may include fiber glass reinforced plastic (FRP).

The active area AA and the non-active area NA may be defined on the substrate SUB. The active area AA may include the first active area AA1 and the second active area AA2. The pixels PX and the first optical sensors PS1 may be located in the first active area AA1 on the substrate SUB, and the pixels PX and the second optical sensors PS2 may be located in the second active area AA2 on the substrate SUB.

A panel circuit layer TFTL (for example, a pixel circuit layer or a thin film transistor layer) may be disposed on the substrate SUB. The panel circuit layer TFTL may include a barrier layer 110 (or a buffer layer), a first thin film transistor TFT1 provided in each pixel PX, and a second thin film transistor TFT2 provided in each optical sensor PS. For example, the first thin film transistor TFT1 may be the driving transistor DT of FIG. 5 or one of the first to sixth transistors T1 to T6, and the second thin film transistor TFT2 may be one of the first to third sensing transistors LT1 to LT3 of FIG. 5. The panel circuit layer TFTL may further include the other circuit elements (for example, the other transistors and the capacitor Cst) included in the pixel driver PDU of each pixel PX, the other circuit elements (for example, the other sensing transistors) included in the sensing driver SDU of each optical sensor PS, and lines connected to the pixels PX and the optical sensors PS.

The barrier layer 110 may be disposed on the substrate SUB. The barrier layer 110 may include silicon nitride, silicon oxide, silicon oxynitride, or the like.

An active layer (or a semiconductor pattern) of each of the thin film transistors TFT may be disposed on the barrier layer 110. The active layer may include polycrystalline silicon, monocrystalline silicon, low-temperature polycrystalline silicon, amorphous silicon, or an oxide semiconductor. The oxide semiconductor may include, for example, a binary compound (ABx), a ternary compound (ABxCy), or a quaternary compound (ABxCyDz) including indium, zinc, gallium, tin, titanium, aluminum, hafnium (Hf), zirconium (Zr), magnesium (Mg) and the like.

The active layer of the first thin film transistor TFT1 may include a first channel region A1, and a first source region S1 and a first drain region D1 that are doped with impurities and have conductivity. The first channel region A1 may overlap a first gate electrode G1 in the third direction DR3 that is the thickness direction of the substrate SUB. The first source region S1 and the first drain region D1 may not overlap the first gate electrode G1.

The active layer of the second thin film transistor TFT2 may include a second channel region A2, and a second source region S2 and a second drain region D2 that are doped with impurities and have conductivity. The first channel region A1 may overlap a second gate electrode G2 in the third direction DR3 that is the thickness direction of the substrate SUB. The second source region S2 and the second drain region D2 may not overlap the second gate electrode G2.

A first insulating layer 120 (for example, a gate insulating layer) may be disposed on the active layers of the thin film transistors TFT. In an embodiment, the first insulating layer 120 may include an inorganic layer, for example, a silicon nitride layer, a silicon oxynitride layer, a silicon oxide layer, a titanium oxide layer, or an aluminum oxide layer.

The gate electrode of each of the thin film transistors TFT may be disposed on the first insulating layer 120. For example, the first gate electrode G1 of the first thin film transistor TFT1 and the second gate electrode G2 of the second thin film transistor TFT2 may be disposed on the first insulating layer 120. In an embodiment, the gate electrodes may include any one of molybdenum (Mo), aluminum (Al), chromium (Cr), gold (Au), titanium (Ti), nickel (Ni), neodymium (Nd) and copper (Cu) or an alloy thereof, but are not limited thereto.

In an embodiment, the first electrode of the capacitor Cst of FIG. 5 or at least one line may be further disposed on the first insulating layer 120.

A second insulating layer 130 (for example, a first interlayer insulating layer) may be disposed on the gate electrodes of the thin film transistors TFT. In an embodiment, the second insulating layer 130 may include an inorganic layer, for example, a silicon nitride layer, a silicon oxynitride layer, a silicon oxide layer, a titanium oxide layer, or an aluminum oxide layer.

In an embodiment, the second electrode of the capacitor Cst of FIG. 5 or at least one line may be disposed on the second insulating layer 130.

A third insulating layer 140 (for example, a second interlayer insulating layer) may be disposed on the second insulating layer 130 or the second electrode of the capacitor Cst. In an embodiment, the third insulating layer 140 may include the same material as the second insulating layer 130. In another embodiment, the second electrode of the capacitor Cst may be disposed on the same layer as first anode connection electrodes ANE11 and ANE21, and the third insulating layer 140 may be omitted.

The first anode connection electrodes ANE11 and ANE21 may be disposed on the third insulating layer 140. The first anode connection electrodes ANE11 and ANE21 may be connected to the drain regions D1 and D2 (or the source regions S1 and S2) of the respective thin film transistors TFT through respective contact holes penetrating the first insulating layer 120, the second insulating layer 130, and the third insulating layer 140. In an embodiment, the first anode connection electrodes ANE11 and ANE21 may include any one of molybdenum (Mo), aluminum (Al), chromium (Cr), gold (Au), titanium (Ti), nickel (Ni), neodymium (Nd) and copper (Cu) or an alloy thereof, but are not limited thereto.

A fourth insulating layer 151 (for example, a first planarization layer) may be disposed on the first anode connection electrodes ANE11 and ANE21. The fourth insulating layer 151 may flatten a stepped portion formed by the thin film transistors TFT. In an embodiment, the fourth insulating layer 151 may include an organic layer such as acryl resin, epoxy resin, phenolic resin, polyamide resin, polyimide resin and the like.

Second anode connection electrodes ANE12 and ANE22 may be disposed on the fourth insulating layer 151. The second anode connection electrodes ANE12 and ANE22 may be connected to the first anode connection electrodes ANE11 and ANE21 through contact holes penetrating the fourth insulating layer 151, respectively. In an embodiment, the second anode connection electrodes ANE12 and ANE22 may include the same material as the first anode connection electrodes ANE11 and ANE21.

A fifth insulating layer 153 (for example, a second planarization layer) may be disposed on the second anode connection electrodes ANE12 and ANE22. In an embodiment, the fifth insulating layer 153 may include the same material as the fourth insulating layer 151.

A photoelectric element layer PEL may be disposed on the fifth insulating layer 153. The photoelectric element layer PEL may include the light emitting element EL of each of the pixels PX, the photoelectric conversion element PD (for example, the first photoelectric conversion element PD1 of the first optical sensor PS1 and the second photoelectric conversion element PD2 of the second optical sensor PS2) of each of the optical sensors PS, and the bank 160. Each light emitting element EL may include a pixel electrode 171, a light emitting layer 173, and a common electrode 180, and each photoelectric conversion element PD may include a first electrode 175, a photoelectric conversion layer 177, and the common electrode 180. The light emitting elements EL and the photoelectric conversion elements PD may share the common electrode 180.

The pixel electrode 171 of the light emitting element EL may be disposed on the fifth insulating layer 153. The pixel electrode 171 may be provided for each pixel PX. The pixel electrode 171 may be connected to the second anode connection electrode ANE12 through the contact hole penetrating the fifth insulating layer 153.

In an embodiment, the pixel electrode 171 of the light emitting element EL may have a single-layer structure of molybdenum (Mo), titanium (Ti), copper (Cu) or aluminum (Al), or may have a stacked-layer structure, for example, a multilayer structure of ITO/Mg, ITO/MgF, ITO/Ag, and ITO/Ag/ITO including indium-tin-oxide (ITO), indium-zinc-oxide (IZO), zinc oxide (ZnO), indium oxide (In₂O₃) and silver (Ag), magnesium (Mg), aluminum (Al), platinum (Pt), lead (Pb), gold (Au), or nickel (Ni).

Further, the first electrode 175 of the photoelectric conversion element PD may be disposed on the fifth insulating layer 153. The first electrode 175 may be provided for each optical sensor PS. For example, the first electrode 175 of the first photoelectric conversion element PD1 may be disposed in the first sensing area SA1 of the first optical sensor PS1, and the first electrode 175 of the second photoelectric conversion element PD2 may be disposed in the second sensing area SA2 of the second optical sensor PS2. The first electrode 175 may be connected to the second anode connection electrode ANE22 of the corresponding optical sensor PS through the contact hole penetrating the fifth insulating layer 153.

In an embodiment, the first electrode 175 of the photoelectric conversion element PD may have a single-layer structure of molybdenum (Mo), titanium (Ti), copper (Cu), or aluminum (Al), or may have a multilayer structure of ITO/Mg, ITO/MgF, ITO/Ag, and ITO/Ag/ITO. However, the embodiments are not limited thereto, and the material or structure of the first electrode 175 of the photoelectric conversion element PD may vary according to embodiments.

The bank 160 may be disposed on the pixel electrode 171 and the first electrode 175. The bank 160 may be formed in the region (for example, the upper portion of the edge of the pixel electrode 171) overlapping the pixel electrode 171, and may include an opening exposing a part of the pixel electrode 171. The region where the exposed pixel electrode 171 and the light emitting layer 173 overlap (or, the region including the same) may be defined as the emission area EA of each pixel PX.

Further, the bank 160 may be formed in the region (for example, the upper portion of the edge of the first electrode 175) overlapping the first electrode 175, and may include an opening exposing the first electrode 175. The opening exposing the first electrode 175 may provide a space in which the photoelectric conversion layer 177 of each optical sensor PS is formed. The region where the exposed first electrode 175 and the photoelectric conversion layer 177 overlap (or the region including the same) may be defined as the light sensing area (for example, the first sensing area SA1 of the first optical sensor PS1 or the second sensing area SA2 of the second optical sensor PS2). For example, the bank 160 may be disposed around the emission areas EA and the first and second sensing areas SA1 and SA2 to surround the emission areas EA and the first and second sensing areas SA1 and SA2.

In an embodiment, the bank 160 may include an organic insulating material selected from the group consisting of acrylic resin, epoxy resin, phenolic resin, polyamide resin, polyimide resin, unsaturated polyester resin, polyphenylene ether resin, polyphenylenesulfide resin and benzocyclobutene (BCB). Alternatively, the bank 160 may include an inorganic material such as silicon nitride. The material of the bank 160 may vary according to embodiments.

The light emitting layer 173 may be disposed on the pixel electrode 171 of the light emitting element EL exposed by the opening of the bank 160. The light emitting layer 173 may include a high molecular material or a low molecular material. Light emitted from the light emitting layer 173 may contribute to image display. In an embodiment, the light emitting layer 173 may be provided for each pixel PX, and the light emitting layer 173 of each pixel PX may emit visible light of a color corresponding to the corresponding pixel PX. In another embodiment, the light emitting layer 173 may be a common layer shared by the pixels PX of different colors, and a wavelength conversion layer corresponding to a color (or a wavelength band) of light to be emitted from each of the pixels PX may be disposed in the emission areas EA of at least some of the pixels PX.

When the light emitting layer 173 is formed of an organic material, a hole injection layer and a hole transporting layer may be disposed under each light emitting layer 173, and an electron injection layer and an electron transporting layer may be stacked on each light emitting layer 173. They may be a single layer or a multilayer formed of an organic material.

The photoelectric conversion layer 177 may be disposed on the first electrode 175 of the photoelectric conversion element PD exposed by the opening of the bank 160. The photoelectric conversion layer 177 may generate photocharges corresponding to (for example, in proportion to) incident light. Electric charges generated and accumulated in the photoelectric conversion layer 177 may be converted into electrical signals required for light sensing (e.g., fingerprint sensing).

The photoelectric conversion layer 177 may include an electron donating material and an electron accepting material. The electron donating material may generate donor ions in response to light, and the electron accepting material may generate acceptor ions in response to light.

In an embodiment, when the photoelectric conversion layer 177 is formed of an organic material, the electron donating material may include a compound such as subphthalocyanine (SubPc) or dibutylphosphate (DBP), but is not limited thereto. The electron accepting material may include a compound such as fullerene, a fullerene derivative, or perylene diimide, but is not limited thereto. In another embodiment, when the photoelectric conversion layer 177 is formed of an inorganic material, the photoelectric conversion element PD may be a PN type or PIN type phototransistor.

When the photoelectric conversion layer 177 is formed of an organic material, a hole injection layer and a hole transporting layer may be disposed under each photoelectric conversion layer 177, and an electron injection layer and an electron transporting layer may be disposed above each photoelectric conversion layer 177. They may be a single layer or a multilayer formed of an organic material.

In an embodiment, the first sensing area SA1 may be an area that receives light having the same wavelength as that of light generated from the emission area EA of an adjacent pixel PX while using the light as a light source. For example, the first sensing area SA1 may receive light having the same wavelength as that of light (for example, green light) generated from the third emission area EA3 of at least one adjacent third color pixel PX3 while using the light a light source.

The common electrode 180 may be disposed on the light emitting layer 173, the photoelectric conversion layer 177, and the bank 160. The common electrode 180 may be disposed across the pixels PX and the optical sensors PS to cover the light emitting layer 173, the photoelectric conversion layer 177, and the bank 160. In an embodiment, the common electrode 180 may include a conductive material having a low work function, for example, Li, Ca, LiF/Ca, LiF/Al, Al, Mg, Ag, Pt, Pd, Ni, Au Nd, Ir, Cr, BaF, Ba, or a compound or mixture thereof (e.g., a mixture of Ag and Mg, etc.). Alternatively, the common electrode 180 may include a transparent metal oxide, for example, indium-tin-oxide (ITO), indium-zinc-oxide (IZO), zinc oxide (ZnO) or the like.

An encapsulation layer ENL may be disposed on the photoelectric element layer PEL. In an embodiment, the encapsulation layer ENL may include at least one inorganic layer and one organic layer to protect each of the light emitting layer 173 and the photoelectric conversion layer 177 from permeation of oxygen or moisture or foreign matter such as dust. For example, the encapsulation layer ENL may have a structure in which a first inorganic layer 191, an organic layer 193, and a second inorganic layer 195 are sequentially stacked. In an embodiment, the first inorganic layer 191 and the second inorganic layer 195 may be formed of multiple layers in which one or more inorganic layers of a silicon nitride layer, a silicon oxynitride layer, a silicon oxide layer, a titanium oxide layer and an aluminum oxide layer are alternately stacked. In an embodiment, the organic layer 193 may be an organic layer such as acryl resin, epoxy resin, phenolic resin, polyamide resin, polyimide resin or the like.

The color filter layer CFL may be disposed above the encapsulation layer ENL. The color filter layer CFL may include the light blocking member LS and the color filters CF. The color filter layer CFL may further include the first overcoat layer OC1 covering the light blocking member LS and the color filters CF.

The light blocking member LS may be disposed in the active area AA including the first active area AA1 and the second active area AA2. The light blocking member LS may include the first openings OPN1 corresponding to the emission areas EA of the pixels PX and the second openings OPN2 corresponding to the first sensing areas SA1 of the first optical sensors PS1. For example, the light blocking member LS may include the first openings OPN1 exposing the light emitting elements EL of the pixels PX and the second openings OPN2 exposing the first photoelectric conversion elements PD1 of the first optical sensors PS1. The light blocking member LS may surround the emission areas EA and the first sensing areas SA1.

FIGS. 8 and 9 illustrate that the first openings OPN1 and the second openings OPN2 of the light blocking member LS are aligned with the opening area of the bank 160, but embodiments are not limited thereto. For example, the size (for example, area) of the first openings OPN1 or the second openings OPN2 of the light blocking member LS may be changed in consideration of the light emission characteristics or viewing angles of the pixels PX, the light receiving rates of the first optical sensors PS1, and the like. For example, the light blocking member LS may be opened wider than the bank 160 in portions corresponding to the first emission areas EA1 and the first sensing areas SA1.

The light blocking member LS may cover the second photoelectric conversion elements PD2 of the second optical sensors PS2. For example, the light blocking member LS may be disposed above the second photoelectric conversion elements PD2 in each second sensing area SA2 to completely cover each second photoelectric conversion element PD2.

The light blocking member LS may be formed of a material capable of blocking light. For example, the light blocking member LS may be formed of a photosensitive resin including an organic black pigment or an inorganic black pigment such as carbon black or the like.

The color filters CF may include the first color filters CF1 for selectively transmitting the first light of the first color, the second color filters CF2 for selectively transmitting the second light of the second color, and third color filters CF3 for selectively transmitting the third light of the third color.

The first color filters CF1 may be located in the first emission areas EA1 to be disposed on the light emitting elements EL of the first color pixels PX1. For example, the first color filters CF1 may be disposed in the first openings OPN1 (for example, the first color pixels PX of a first group corresponding to the first color pixels PX1) of the light blocking member LS exposing the light emitting elements EL of the first color pixels PX1.

The second color filters CF2 may be located in the second emission areas EA2 to be disposed on the light emitting elements EL of the second color pixels PX2. For example, the second color filters CF2 may be disposed in the first openings OPN1 (for example, the first openings OPN1 of a second group corresponding to the second color pixels PX2) of the light blocking member LS exposing the light emitting elements EL of the second color pixels PX2.

In an embodiment, the first color filters CF1 and the second color filters CF2 may also be located in the second sensing areas SA2 to be disposed on the second photoelectric conversion elements PD2 of the second optical sensors PS2. For example, the first color filters CF1 and the second color filters CF2 may be disposed to overlap each other on the light blocking member LS covering the second photoelectric conversion elements PD2. The light blocking member LS, the first color filter CF1, and the second color filter CF2, which are disposed to overlap each other in each of the second sensing areas SA2, may constitute or form the light blocking layer (hereinafter, referred to as “first light blocking layer LBP1”) provided on the second photoelectric conversion element PD2. Accordingly, the light blocking rate for the second photoelectric conversion elements PD2 may be increased. In each second sensing area SA2, the light blocking member LS, the first color filter CF1, and the second color filter CF2 may be sequentially disposed or stacked, and the arrangement order thereof may vary according to embodiments.

In an embodiment, each of the first color filter CF1 and the second color filter CF located in each second sensing area SA2 may completely cover the second photoelectric conversion element PD2 located in the second sensing area SA2. Accordingly, it is possible to more effectively block external light from being incident on the second optical sensors PS2.

The third color filters CF3 may be located in the third emission areas EA3 to be disposed on the light emitting elements EL of the third color pixels PX3. For example, the third color filters CF3 may be disposed in the first openings OPN1 (for example, the first openings OPN1 of a third group corresponding to the third color pixels PX3) of the light blocking member LS exposing the light emitting elements EL of the third color pixels PX3.

In an embodiment, the third color filters CF3 may also be located in the first sensing areas SA1 to be disposed on the first photoelectric conversion elements PD1 of the first optical sensors PS1. For example, the third color filters CF3 may be disposed in the second openings OPN2 of the light blocking member LS exposing the first photoelectric conversion elements PD1 of the first optical sensors PS1. Accordingly, light of a desired color or wavelength band may be selectively transmitted through the first sensing areas SA1. For example, the first optical sensors PS1 may output first sensing signals according to the amount of received light while using the third light emitted from adjacent third color pixels PX3 as a light source.

The first overcoat layer OC1 may be a capping layer for protecting the color filters CF, and may include an inorganic layer. For example, the first overcoat layer OC1 may contain silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or the like.

The window WDL may be disposed on the color filter layer CFL. The window WDL may be formed of, for example, a glass substrate, a plastic substrate, or a protective film, and the material thereof is not limited thereto.

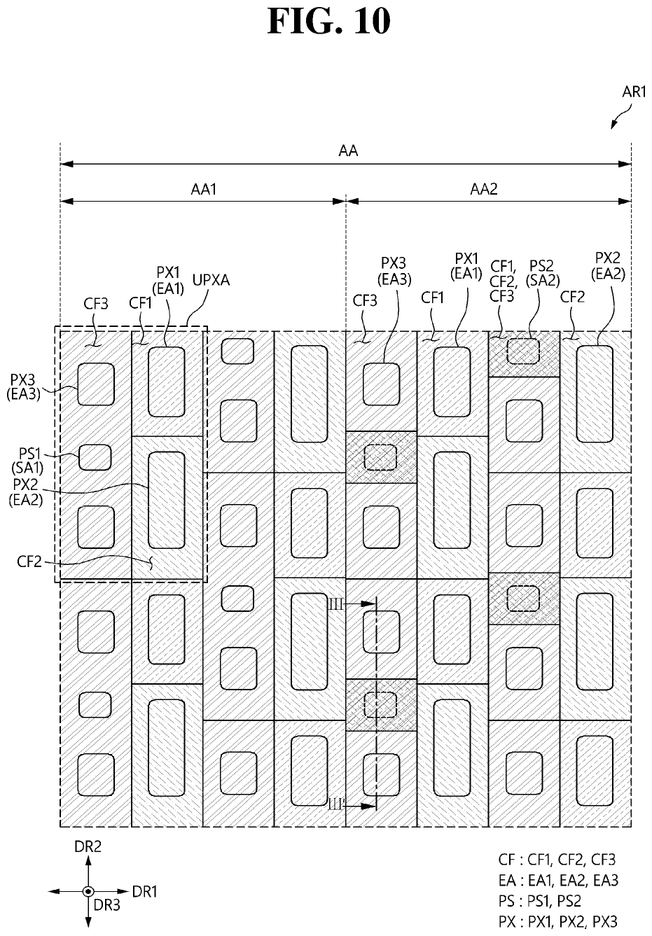

FIG. 10 is a plan view illustrating the arrangement structure of the pixels PX, the optical sensors PS, and the color filters CF according to an embodiment. FIG. 11 is a cross-sectional view showing an example of a cross section taken along line III-III′ of FIG. 10. In the embodiments of FIGS. 10 and 11, like reference numerals will be given to like or corresponding elements of the previously described embodiment (for example, the embodiment of FIGS. 6 to 9), and a detailed description thereof will be omitted.

Referring to FIGS. 10 and 11 in addition to FIGS. 1 to 9, the color filter layer CFL may further include the third color filters CF3 located in the second sensing areas SA2. For example, the third color filter CF3 disposed on the light blocking member LS and overlapping the second photoelectric conversion element PD2, the first color filter CF1, and the second color filter CF2 may be provided in in each second sensing area SA2. The light blocking member LS, the first color filter CF1, the second color filter CF2, and the third color filter CF3, which are disposed to overlap each other in each of the second sensing areas SA2, may constitute or form the light blocking layer (hereinafter, referred to as “second light blocking layer LBP2”) provided on the second photoelectric conversion element PD2. The stacking order of the light blocking member LS, the first color filter CF1, the second color filter CF2, and the third color filter CF3 provided in each second sensing area SA2 is not limited, and may vary according to embodiments.

In an embodiment, the third color filters CF3 may be disposed to completely cover the second photoelectric conversion elements PD2 in the second sensing areas SA2. The third color filters CF3 provided in the second sensing areas SA2 may shield the second photoelectric conversion elements PD2 together with the light blocking member LS, the first color filters CF1, and the second color filters CF2 in the second sensing areas SA2, thereby blocking external light from being incident on the second photoelectric conversion elements PD2.

As in the above-described embodiments, by overlapping the light blocking member LS and at least two color filters CF on the second photoelectric conversion elements PD2, the light blocking rate may be increased. For example, the light blocking member LS, the first color filter CF1, and the second color filter CF2 may be disposed on the second photoelectric conversion element PD2 to provide the first light blocking layer LBP1 in each second sensing area SA2 as in the embodiment of FIGS. 6 to 9, or the light blocking member LS, the first color filter CF1, the second color filter CF2, and the third color filter CF3 may be disposed on the second photoelectric conversion element PD2 to provide the second light blocking layer LBP2 in each second sensing area SA2 as in the embodiment of FIGS. 10 and 11. Accordingly, external light may be effectively blocked without significantly increasing the thickness of the light blocking member LS (for example, about 3 times or more).

In embodiments, the type or number of the color filters CF for shielding the second photoelectric conversion element PD2 may be selected in consideration of a light transmittance, a level of difficulty of processing of the display panel 10, or a defect rate. For example, when the light transmittance set to a target value (for example, the light transmittance set to 1% or less, 0.001% or less, or 0.0001% or less) may be sufficiently achieved by providing the light blocking member LS, the first color filter CF1, and the second color filter CF in the second sensing area SA2, the first light blocking layer LBP1 in which only the light blocking member LS, the first color filter CF1, and the second color filter CF2 overlap may be disposed without disposing the third color filter CF3 in each second sensing area SA2. Accordingly, the height or thickness of the light blocking layer for shielding the second photoelectric conversion element PD2 may be reduced or minimized. Accordingly, the display panel 10 may be manufactured more easily or smoothly, and the defect rate may be reduced. Meanwhile, when it is required to lower the external light transmittance to the second optical sensors PS2 provided in the second active area AA2, the second light blocking layer LBP2 in which all the light blocking member LS, the first color filter CF1, the second color filter CF2, and the third color filter CF3 overlap may be disposed in each second sensing area SA2.

Further, in embodiments, the light blocking layer (for example, the first light blocking layer LBP1 or the second light blocking layer LBP2) may be formed on the second optical sensors PS2 using the light blocking member LS and the color filters CF that are provided adjacent thereto. Accordingly, the light blocking layer may be easily or appropriately formed without adding a separate mask process or the like.

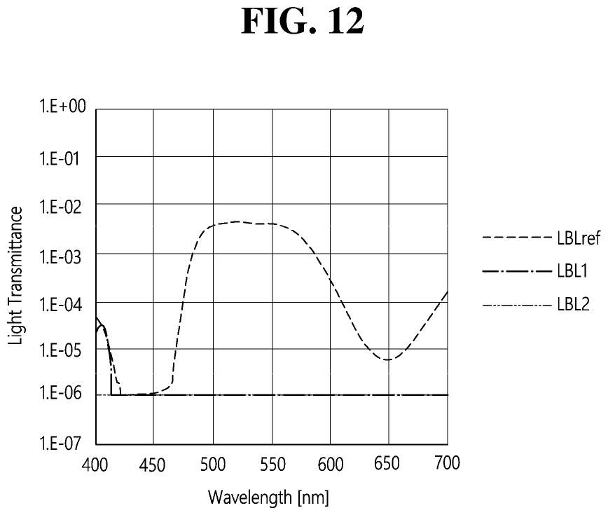

FIG. 12 is a graph showing light transmittances of light blocking layers according to embodiments.

Referring to FIG. 12, the light transmittance may vary according to the configuration or structure of the light blocking layer. For example, when the light blocking layer (hereinafter, referred to as “reference light blocking layer LBLref”) is formed by overlapping only the light blocking member LS and the third color filter CF3, the light transmittance of the reference light blocking layer LBPref for the third light (for example, green light of a wavelength band of about 480 nm to 560 nm) may be in a range of about 0.001 (0.1%) to 0.01 (1%).

On the other hand, when the first light blocking layer LBL1 is formed by overlapping the light blocking member LS, the first color filter CF1, and the second color filter CF2 according to an embodiment, the light transmittance of the first light blocking layer LBL1 for at least the third light may be lowered to about 10-6 (0.0001%) or less. For example, in the wavelength band corresponding to the third light, the light blocking rate of the first light blocking layer LBL1 may be substantially similar to or the same as the light blocking rate of the second light blocking layer LBL2.

When the second light blocking layer LBL2 is formed by overlapping the light blocking member LS, the first color filter CF1, the second color filter CF2, and the third color filter CF3 according to another embodiment, the light transmittance of the second light blocking layer LBL2 for the third light may be about 10⁻⁶ (0.0001%) or less. Further, the light transmittance of the second light blocking layer LBL2 for the second light (for example, blue light of a wavelength band of about 370 nm to about 460 nm) may be lowered to about 10⁻⁶ (0.0001%) or less.

Therefore, an appropriate light blocking layer may be formed above the second optical sensors PS2 in consideration of the wavelength band of light to be blocked using the light blocking layer, the target light transmittance (or light blocking rate), the structure or thickness of the display panel 10, or the manufacturing efficiency of the display panel 10. For example, when a fingerprint or the like is sensed using the third light emitted from the third pixels PX3, noise generated from the display panel 10 may be more accurately sensed by forming the first light blocking layer LBP1 of which thickness is reduced or minimized while effectively blocking the third light in the second sensing area SA2.

As described above, the display device 1 according to the embodiments may include the first optical sensor PS1 disposed in the first active area AA1 and including the first photoelectric conversion element PD1, and the second optical sensor PS2 disposed in the second active area AA2 and including the second photoelectric conversion element PD2. Further, the display device 1 may include the light blocking member LS, and the first and second color filters CF1 and CF2 that are disposed to overlap each other above the second photoelectric conversion element PD2.

In accordance with embodiments, it is possible to effectively block external light from being incident on the second photoelectric conversion element PD2. Accordingly, the noise generated from the display panel 10 may be effectively sensed using the second optical sensor PS2, and the performance of the light sensing unit (for example, a fingerprint sensor provided or formed inside the display panel 10) including the first optical sensor PS1 and the second optical sensor PS2 may be improved. For example, noise included in the first sensing signal inputted from the first optical sensor PS1 may be removed while utilizing noise sensed using the second optical sensor PS2. Accordingly, a user's input (for example, a fingerprint input) generated in the first active area AA1 may be more accurately sensed, and the performance (for example, sensitivity) of the light sensing unit may be improved.

Although embodiments of the present inventive concepts have been described, various modifications and similar arrangements of such embodiments will be apparent to a person of ordinary skill in the art. Accordingly, the inventive concepts are not limited to such embodiments, but rather to the scope and spirit of the appended claims.

What is claimed is:

1. A display device comprising:
an active area comprising a first active area and a second active area;
pixels disposed in the first active area and the second active area and comprising respective light emitting elements;
a first optical sensor disposed in the first active area and comprising a first photoelectric conversion element;
a second optical sensor disposed in the second active area and comprising a second photoelectric conversion element;
a light blocking member disposed in the first active area and the second active area, comprising first openings exposing the light emitting elements and a second opening exposing the first photoelectric conversion element, and covering the second photoelectric conversion element; and
a first color filter and a second color filter disposed on the light blocking member and overlapping each other above the second photoelectric conversion element.

2. The display device of claim 1, wherein the light blocking member completely covers the second photoelectric conversion element.

3. The display device of claim 2, wherein each of the first color filter and the second color filter completely covers the second photoelectric conversion element.

4. The display device of claim 1, wherein the second active area is located at an edge of the active area.

5. The display device of claim 1, further comprising a third color filter disposed in the second opening to overlap the first photoelectric conversion element.

6. The display device of claim 5, wherein the first color filter is a red color filter,
the second color filter is a blue color filter, and
the third color filter is a green color filter.

7. The display device of claim 5, wherein the pixels comprise first color pixels, second color pixels, and third color pixels.

8. The display device of claim 7, further comprising:
first color filters disposed in first openings of a first group exposing light emitting elements of the first color pixels among the first openings;
second color filters disposed in first openings of a second group exposing light emitting elements of the second color pixels among the first openings; and
third color filters disposed in first openings of a third group exposing light emitting elements of the third color pixels among the first openings.

9. The display device of claim 1, further comprising a third color filter disposed on the light blocking member, and overlapping the first color filter and the second color filter above the second photoelectric conversion element.

10. The display device of claim 9, wherein the third color filter completely covers the second photoelectric conversion element.

11. A display device comprising:
a substrate comprising a first active area and a second active area;
pixels disposed on the substrate to be located in the first active area and the second active area, and comprising respective light emitting elements;
first optical sensors disposed on the substrate to be located between pixels located in the first active area, and comprising respective first photoelectric conversion elements;
second optical sensors disposed on the substrate to be located between pixels located in the second active area, and comprising respective second photoelectric conversion elements;
a light blocking member disposed above at least the second photoelectric conversion elements, and completely covering the second photoelectric conversion elements; and
first color filters and second color filters disposed on the light blocking member, and overlapping each other above the second photoelectric conversion elements.

12. The display device of claim 11, wherein the first color filters and the second color filters completely cover the second photoelectric conversion elements.

13. The display device of claim 11, wherein the first color filters are red color filters, and
the second color filters are blue color filters.

14. The display device of claim 11, further comprising third color filters disposed on the light blocking member, and overlapping the first color filters and the second color filters above the second photoelectric conversion elements.

15. The display device of claim 14, wherein the third color filters are green color filters.

16. The display device of claim 14, wherein the third color filters completely cover the second photoelectric conversion elements.

17. The display device of claim 11, wherein the light blocking member is disposed in the first active area and the second active area, and comprises first openings exposing at least a part of each of the light emitting elements and second openings exposing at least a part of each of the first photoelectric conversion elements.

18. The display device of claim 17, wherein the pixels comprise first color pixels, second color pixels, and third color pixels.

19. The display device of claim 18, further comprising:
first color filters disposed in first openings of a first group exposing light emitting elements of the first color pixels among the first openings;
second color filters disposed in first openings of a second group exposing light emitting elements of the second color pixels among the first openings; and
third color filters disposed in the second openings and first openings of a third group exposing light emitting elements of the third color pixels among the first openings.

20. The display device of claim 11, wherein the first active area is located at a center of an active area comprising the first active area and the second active area, and
the second active area is located at an edge of the active area.
